(19) United States
(12) Patent Application Publication
(10) Pub. No.: US 2002/0011604 A1
(43) Pub. Date: Jan. 31, 2002

(54) Semiconductor device for milliwave band oscillation, fabricating method therefor and oscillator therewith

(76) Inventors: Motoji Yagura, Tenri-shi (JP); John Kevin Twynam, Tenri-shi (JP)

Correspondence Address: BIRCH STEWART KOLASCH & BIRCH, PO BOX 747, FALLS CHURCH, VA, 22040-0747, US

(21) Appl. No.: 09/915,499

(22) Filed: Jul. 27, 2001

(30) Foreign Application Priority Data
Jul. 28, 2000 (JP) 2000-228805
Jun. 14, 2001 (JP) 2001-180097

(51) Int. Cl. H01L 31/0328; H01L 31/0336; H01L 31/072; H01L 31/109

(52) U.S. Cl. 257/194

(57) ABSTRACT

A semiconductor device for milliwave band oscillation has a Gunn diode and a Schottky diode epitaxially formed on a same substrate and connected by a transmission line. The Gunn diode is provided with an anode-ohmic electrode and a cathode-ohmic electrode. The Schottky diode is provided with a Schottky electrode formed on an active layer of n-GaAs and an ohmic electrode formed on an ohmic electrode forming high-density layer. Formation of the Schottky electrode on the active layer having a low carrier density makes it possible not only to satisfactorily obtain the Schottky characteristic of the Schottky electrode but also to require no annealing at a high temperature after ion implantation for forming other active devices. Thus, epitaxial structure deterioration and contact resistance deterioration of the semiconductor device are prevented.

### BACKGROUND OF THE INVENTION

The present invention relates to a semiconductor device in which different compound semiconductor elements are integratedly formed and to a milliwave/microwave band oscillator employing the semiconductor device.

In recent years, there have been developed systems using the milliwave band and the microwave band.

Particularly in systems using the milliwave band (30 to 90 GHz), transistors such as a HBT (hetero-junction bipolar transistor) and a HEMT (high-electron-mobility transistor) are used for an oscillation element and an amplifier, and a Schottky diode is used for a varactor and a mixer. Furthermore, those elements are fabricated on a same substrate for integration of the elements, which is disclosed in Japanese Patent Laid-Open Publication Nos. HEI 3-64929 and SHO 63-129656.

However, when a HBT or a HEMT is employed as an oscillation element in the milliwave band, it is required to reduce emitter width to 1 μm or less and gate width to 0.2 μm or less for a fine structure in order to cope with the increase in frequency of the transistor. In compliance with the dimensional reduction, it is also required to reduce the parasitic capacitance and the parasitic resistance.

For achievement of such a fine structure, complicated processes are required and a reduction in yield is caused. Furthermore, the amount of current is reduced when the emitter width and the gate width are reduced for the fine structure, and this has led to difficulty in obtaining a necessary output power from the oscillation element.

In order to solve these disadvantages, it can be considered to employ a diode having a negative resistance as an oscillation element instead of employing a HBT or a HEMT. One example is disclosed in Japanese Patent Laid-Open Publication No. HEI 1-112827. Its structure and fabrication method will be described with reference to FIGS. 5A through 5C.

With regard to the structure, as shown in FIG. 5C, an electrode constructed of a TiW film 806/Au film 807 is provided on a p⁺-GaAs layer 805, and an electrode constructed of Ti 808/Au 809 is provided on an n⁺-GaAs layer 802, so as to constitute an IMPATT (impact ionization avalanche transit time) diode having a negative resistance. Moreover, a microstrip patch constructed of a Ti film 810/Au film 811 is formed on a semi-insulating GaAs substrate 801. Furthermore, this example discloses capability of integrating another device on the substrate 801 and capability of integrating another device by utilizing the n⁺-GaAs layer 802.

In the fabricating method of this example, first of all, as shown in FIG. 5A, an n⁺-GaAs layer 802 (having a density of 1×10¹⁹ cm⁻³ and a thickness of 1.5 μm), an n-GaAs layer 803 (having a density of 2×10¹⁷ cm⁻³ and a thickness of 0.25 μm), a p-GaAs layer 804 (having a density of 2×10¹⁷ cm⁻³ and a thickness of 0.25 μm) and a p⁺-GaAs layer 805 (having a density of 1×10¹⁹ cm⁻³ and a thickness of 0.2 μm) are successively epitaxially grown on the semi-insulating GaAs substrate 801. Next, a photoresist is applied, and a circle of 5 μm is patterned to form an electrode constructed of a TiW film 806 (having a thickness of 100 nm)/Au film 807 (400 nm).

Next, as shown in FIG. 5A, the p⁺-GaAs layer 805, the p-GaAs layer 804, the n-GaAs layer 803 and the n⁺-GaAs layer 802 are etched by wet etching using the aforementioned electrode as an etching mask, and the etching is stopped within the n⁺-GaAs layer 802. Next, a photoresist is applied and patterned into a square of a side of 75 μm, and an electrode constructed of a Ti film 808 (100 nm)/Au film 809 (400 nm) is formed as shown in FIG. 5B by the lift-off technology. At this time, the electrodes 808 and 809 are self-aligned with the electrodes 806 and 807.

Next, as shown in FIG. 5C, the n⁺-GaAs layer 802 and part (about 100 nm in depth) of the substrate 801 is subjected to anisotropic plasma etching. Through this process, an IMPATT diode is isolated as a mesa on the semi-insulating substrate 801. Subsequently, a microstrip patch, which is constructed of a Ti film 810 (100 nm)/Au film 811 (400 nm), is formed on the substrate 801 by the lift-off technology.

This document also discloses the following matters. Another device can be integratedly formed on the substrate 801 immediately before the formation of the microstrip patches 810 and 811. In particular, an active device region can be formed by implanting ions into the semi-insulating substrate 801 separately from the regions corresponding to the IMPATT diode and the microstrip patch. Instead of this, an n⁺-type doped GaAs region 802 can be preserved to fabricate a device separately from the regions corresponding to the IMPATT diode and the microstrip patch by means of another photolithographic mask in the process of etching the n⁺-GaAs layer 802.

The thus-fabricated IMPATT diode can cope with the milliwave band even when not made fine. Therefore, the fabricating process becomes easy in comparison with the HBT and HEMT. There is a further merit that a large output power is produced by the oscillation element.

However, the aforementioned prior art examples have the following disadvantages.

(1) In the conventional examples, ion implantation is used as a method for fabricating active devices and so on other than the IMPATT diode on the semi-insulating substrate. However, it is required to perform heat treatment i.e. annealing at a high temperature of about 600° C. after the ion implantation in order to activate the region in which ions have been implanted. This heat treatment disadvantageously causes deterioration in contact resistance and deterioration in the epitaxial structure (deterioration in the heterojunction and deterioration in density profile) of the IMPATT diode previously produced.

(2) In order to reduce the contact resistances of the electrodes 808 and 809, the n⁺-GaAs layer 802, which is the contact layer of the IMPATT diode, is highly doped into the n⁺-type. This high-density n⁺-GaAs layer 802 has a disadvantage that the Schottky characteristics, which are necessary for, for example, the gate electrode of a MESFET and the Schottky electrode of a Schottky diode, cannot be obtained when the n⁺-GaAs layer 802 is utilized for fabrication of the active devices other than the IMPATT diode.

As described above, in the aforementioned prior art examples, even if the diode that has a negative resistance and the Schottky diode are formed on a same substrate, the characteristic variation cannot be reduced, and moreover, no sufficient reproducibility can be obtained.

### SUMMARY OF THE INVENTION

Accordingly, an object of the present invention is to provide a semiconductor device having a negative resistance diode and a Schottky diode integratedly formed on a same diode through easy fabricating processes without contact resistance deterioration and epitaxial structure deterioration.

In order to achieve the aforementioned object, the present invention provides a semiconductor device comprising: a negative resistance diode provided with an anode-ohmic electrode and a cathode-ohmic electrode having a negative resistance diode characteristic and an epitaxial structure; and a Schottky diode provided with an active layer having a negative resistance diode characteristic and an epitaxial structure, a Schottky electrode formed on the active layer, and an ohmic electrode formed on an ohmic electrode forming high-density layer, wherein the negative resistance diode and the Schottky diode are integratedly formed on a same substrate.

According to the present invention, the Schottky electrode is provided on the epitaxial active layer which has the negative resistance diode characteristic. The active layer can be constituted of a low density layer such as n-GaAs. The active layer not only allows the Schottky electrode to have the sufficient Schottky characteristic, but also needs no annealing at a high temperature (for example 600° C.) after ion implantation for forming other active devices. Therefore, the problems of the epitaxial structure deterioration, the contact resistance deterioration and the like can be resolved, allowing loss reduction and miniaturization to be achieved.

In the semiconductor device of one embodiment, the negative resistance diode and the Schottky diode are connected by a transmission line to be integratedly formed on the same substrate.

With this arrangement, the line length is reduced between the negative resistance diode and the Schottky diode since the negative resistance diode, the Schottky diode and the transmission line are integratedly formed on the same substrate. This arrangement is, therefore, very effective in loss reduction of line.

In the semiconductor device of another embodiment, the negative resistance diode is a Gunn diode.

The Gunn diode is an oscillation element having a reduced phase noise.

The present invention also provides a method for fabricating the semiconductor device, comprising the steps of: exposing the active layer by removing by etching an anode-ohmic electrode forming high-density layer or a cathode-ohmic electrode forming high-density layer having the negative resistance diode characteristic and the epitaxial structure; and forming the Schottky electrode on the active layer.

In this embodiment, the Schottky electrode can be formed on a low-density active layer such as n-GaAs layer, and therefore, the satisfactory Schottky characteristic of the Schottky electrode can be obtained and no high temperature annealing is required.

The present invention further provides a method for fabricating a semiconductor device, the semiconductor device having: a negative resistance diode having an epitaxial structure with a negative resistance diode characteristic, an anode-ohmic electrode and a cathode-ohmic electrode, the epitaxial structure having a heterostructure; and a Schottky diode provided with an active layer having with a negative resistance diode characteristic and an epitaxial structure, a Schottky electrode formed on the active layer, and an ohmic electrode formed on an ohmic electrode forming high-density layer, wherein the negative resistance diode and the Schottky diode are integratedly formed on a same substrate, the method comprising the steps of: exposing a wide-band gap layer by removing by etching a cathode-ohmic electrode forming high-density layer; exposing the active layer by removing by etching the wide-band gap layer; and forming the Schottky electrode on the active layer.

The wide bandgap layer is exposed by removing the cathode-ohmic electrode forming high-density layer by etching, and then is removed by selective etching to expose the active layer. Therefore, thickness of this active layer can be controlled by the thickness in epitaxial growth (within the wafer surface). Moreover, variation in the thickness of the active layer among wafers is also be reduced. Therefore, satisfactory reproducibility of the Schottky diode characteristic can be obtained.

In one embodiment of the method for fabricating the semiconductor device, the negative resistance diode is a Gunn diode.

The cathode structure of the Gunn diode is heterostructurally formed in general. Therefore, thickness of the active layer can be controlled within a wafer surface, and variation in thickness among wafers is also reduced. With this arrangement, the satisfactory reproducibility of the Schottky diode characteristic can easily be obtained.

The present invention provides an oscillator having a semiconductor device, comprising: a negative resistance diode provided with an anode-ohmic electrode and a cathode-ohmic electrode having a negative resistance diode characteristic and an epitaxial structure; a Schottky diode provided with an active layer having a negative resistance diode characteristic and an epitaxial structure, a Schottky electrode formed on the active layer, and an ohmic electrode formed on an ohmic electrode forming high-density layer; and a transmission line connecting the negative resistance diode and the Schottky diode, wherein the negative resistance diode, the Schottky diode and the transmission line are integratedly formed on a same substrate; and wherein the negative resistance diode is served as an oscillation element, the Schottky diode is provided for a varactor diode, and the transmission line is provided for an output line and a stub.

According to the oscillator of this embodiment, the transmission line connects the negative resistance diode and the Schottky diode on the same substrate, and is also provided for the output line and the stub. Therefore, line loss and the mounting loss such as wire-bonding loss can be reduced, so that the degradation in performance such as phase noise degradation can be prevented.

Moreover, in one embodiment of the present invention, the negative resistance diode is a Gunn diode.

In this embodiment, the Gunn diode is used as an oscillation element in the oscilltor, and therefore a reduced phase noise can be obtained so that the performance of the oscillator is improved.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a sectional view showing a structure of a semiconductor device according to a first embodiment of the present invention;

FIGS. 2A through 2D are sectional views for explaining a method for fabricating the semiconductor device of the first embodiment of the present invention in order of process;

FIG. 3 is a block diagram of a voltage-controlled oscillator that serves as a milliwave band oscillator according to a second embodiment of the present invention;

FIG. 4 is a sectional view for explaining one process in fabrication according to a modification example of the first embodiment;

FIGS. 5A through 5C are sectional views for explaining a structure of a conventional semiconductor device and a fabricating method therefor;

FIG. 6A is a block diagram of a transmitter provided with the semiconductor device of the first embodiment; and

FIG. 6B is a block diagram of a receiver provided with the semiconductor device of the first embodiment.

### DETAILED DESCRIPTION OF THE PREFERRED EMBODIMENTS

The present invention will be described below with reference to the drawings.

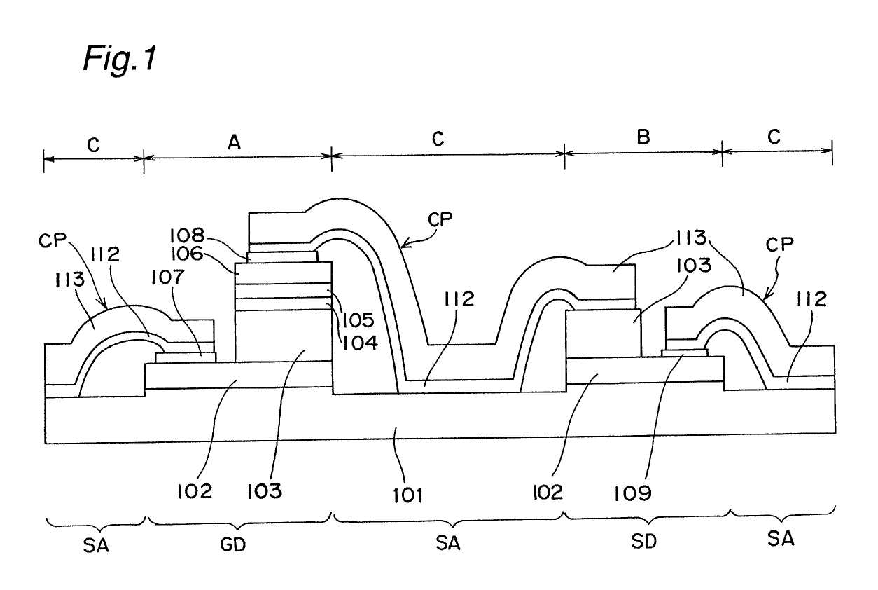

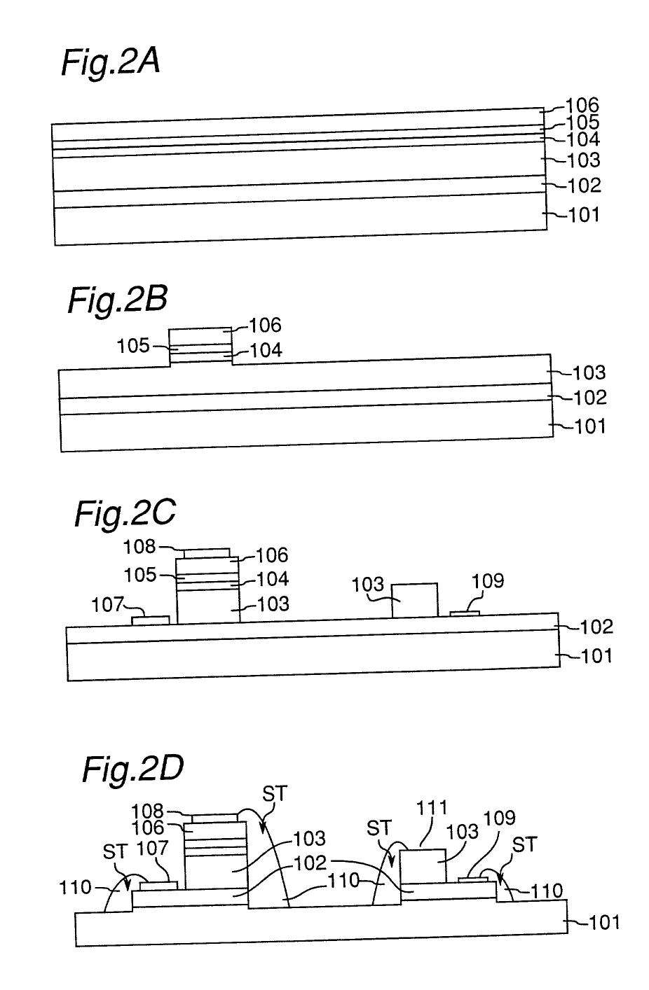

A structure of Gunn diode and Schottky diode integrated circuit according to a first embodiment of this invention will be described with reference to FIG. 1. Thereafter, a fabricating method of the integrated circuit will be described with reference to FIG. 2.

As shown in FIG. 1, in the integrated circuit of this first embodiment, a Gunn diode GD is formed in a region A, a Schottky diode SD is formed in a region B, and a transmission line CP is formed in a region C.

That is, the Gunn diode GD formed in the region A has a cathode-ohmic electrode 108 and an anode-ohmic electrode 107, which are made of AuGe/Ni/Au, and has an active layer 103 made of n-GaAs. On the other hand, the Schottky diode SD formed in the region B has an ohmic electrode 109 made of AuGe/Ni/Au, the active layer 103 and a conductive film 112 made of Ti/Au. The above-mentioned AuGe/Ni/Au is a laminate film in which an Ni film and an Au film are successively laminated on an AuGe film, and the above-mentioned Ti/Au is a laminate film in which an Au film is laminated on a Ti film.

As shown in FIG. 1, peripheries of the Gunn diode GD and the Schottky diode SD are etched, forming an isolated region SA between the Gunn diode GD and the Schottky diode SD.

The transmission line CP formed in the region C is constructed of a conductive film 112 and an Au film 113. A silicon nitride film (not shown) is formed on this transmission line CP.

In the Gunn diode and Schottky diode integrated circuit of this embodiment, a Schottky electrode is formed on the active layer 103 of the Gunn diode GD. The Gunn diode GD is constructed in an epitaxial structure and possesses a negative resistance diode characteristic having. Therefore, the Gunn diode GD and the Schottky diode SD can be integratedly formed on a same substrate through a process that needs no heat treatment (annealing) at a high temperature (600° C.) without utilizing the ion implantation technology nor the contact layer of the IMPATT diode, dissimilarly to the prior art. Therefore, such problems as epitaxial structure deterioration and contact resistance deterioration can be resolved, and loss reduction and miniaturization can be achieved.

Moreover, in this embodiment, the Gunn diode GD having the diode characteristic of negative resistance and the Schottky diode SD are formed on a same GaAs substrate 101 and connected by the transmission line CP. That is, the line size can be reduced by producing the negative resistance diode (Gunn diode GD) that becomes an oscillation element and the Schottky diode SD on the same substrate. Therefore, the above arrangement is very effective in loss reduction. Moreover, by virtue of the negative resistance diode provided by the Gunn diode, the oscillation element of a reduced phase noise and the Schottky diode can be integratedly formed on the same substrate.

The fabricating process of the Gunn diode and Schottky diode integrated circuit of this first embodiment will be described next by sequentially referring to FIGS. 2A through 2D concurrently with a description provided for a detailed structure.

First of all, as shown in FIG. 2A, an n⁺-GaAs layer 102, which becomes an anode-ohmic electrode forming high-density layer, is epitaxially grown to a thickness of 800 nm at an Si doping density of 5×10¹⁸ cm⁻³ on a semi-insulating GaAs substrate 101 by the MBE (molecular beam epitaxial growth), MOCVD (metalorganic chemical vapor deposition) method or the like. Next, an n-GaAs layer 103, which becomes an active layer, is epitaxially grown to a thickness of 2000 nm at an Si doping density of 2×10¹⁶ cm⁻³. Next, a cathode layer n-AlₓGa₁₋ₓAs (X=0.35) layer 104, which is constructed of a wide bandgap layer, is epitaxially grown to a thickness of 50 nm at an Si doping density of 5×10¹⁷ cm⁻³. Further, an n-AlₓGa₁₋ₓAs layer (X=0.35→0) 105 is epitaxially grown to a thickness of 20 nm at an Si doping density of 5×10¹⁷ cm⁻³. Next, an n⁺-GaAs layer 106, which becomes a cathode-ohmic electrode forming high-density layer 106, is epitaxially grown to a thickness of 500 nm at an Si doping density of 5×10¹⁸ cm⁻³.

Next, as shown in FIG. 2B, the n⁺-GaAs layer 106, the n-AlₓGa₁₋ₓAs layer 105 and the n-AlₓGa₁₋ₓAs layer 104 are removed by etching with a region that becomes the cathode of the Gunn diode GD masked with an SiN film, an SiO film or the like, exposing the active layer 103.

With regard to this etching, time etching may be performed by using an etching method that has no selectivity of GaAs and AlGaAs. In the above case, the thickness of the active layer 103 cannot be controlled, and, in addition, the thickness varies also within the wafer surface. The variation in the thickness of this active layer 103 becomes a characteristic variation of the Schottky diode formed subsequently.

Accordingly, by using the etching method with selectivity, this thickness variation can be prevented. In concrete, the n⁺-GaAs layer 106 is removed by etching, and thereafter, the n-AlₓGa₁₋ₓAs layer 105 and the n-AlₓGa₁₋ₓAs layer 104 are removed by hydrofluoric acid. The AlGaAs etching selection ratio of hydrofluoric acid with respect to GaAs is not smaller than one hundred. Therefore, the thickness of the active layer 103 can be controlled to the thickness at the epitaxial growth within the wafer surface. Furthermore, the etching can be stopped by the n-AlₓGa₁₋ₓAs layer 105 or the n-AlₓGa₁₋ₓAs layer 104, whose electron affinity is smaller than that of GaAs. In this case, a Schottky diode with a large Schottky barrier can be formed.

It is also possible to perform etching to the n-AlₓGa₁₋ₓAs layer 105 or the n-AlₓGa₁₋ₓAs layer 104 by the time etching. However, by using an etchant that contains an acid such as citric acid or sulfuric acid and hydrogen peroxide aqueous solution, the GaAs 106 can be etched at a high selection ratio with respect to AlGaAs.

Next, the Schottky region of the Schottky diode SD is masked by a photoresist pattern or the like without removing the SiN film or SiO film, the SiN film or the SiO film remaining in the region that becomes the cathode of the Gunn diode GD. The active layer 103 is then removed by etching so as to expose the anode-ohmic electrode forming high-density layer 102, as shown in FIG. 2C.

When etching the Schottky region, as described above, the mask of SiN film or the SiO film is reused instead of newly forming a cathode region mask of the Gunn diode. Thereby, a smooth etching configuration can be obtained in such a manner that no irregular difference in level exists on the sidewall of the active layer 103 of the Gunn diode. If an irregular difference in level exists on the sidewall of the active layer 103, then a frequency component unnecessary for the oscillation of the Gunn diode is generated. This consequently leads to an oscillation power reduction and an oscillation efficiency reduction.

At this time, if an InGaP layer having a thickness of, for example, 20 nm is interposed as an etching stopper layer between the active layer 103 and the anode-ohmic electrode forming high-density layer 102, then the active layer 103 can be selectively removed by etching, although this arrangement is not adopted by this embodiment.

Next, as shown in FIG. 2C, AuGe (100 nm)/Ni (15 nm)/Au (100 nm) is formed by the vapor deposition method in the region where the anode-ohmic electrode 107 of the Gunn diode GD is formed, the region where the cathode-ohmic electrode 108 is formed and the region where the ohmic electrode 109 of the Schottky diode SD is formed. Then, an ohmic electrode alloying process is performed by heat treatment at a temperature of 390° C. Through this process, the anode-ohmic electrode 107, the cathode-ohmic electrode 108 and the ohmic electrode 109 are formed. The above-mentioned AuGe (100 nm)/Ni (15 nm)/Au (100 nm) is a laminate film obtained by successively laminating an Ni layer of 15 nm and an Au layer of 100 nm on an AuGe layer of a layer thickness of 100 nm.

Next, resist patterning is performed to form a resist mask so that the Gunn diode GD in the region A and the Schottky diode SD in the region B are separated from each other. Then, the n⁺-GaAs layer 102 is etched for mesa isolation as shown in FIG. 2D. At this time, if isolation is performed by ion implantation instead of mesa isolation, then a difference in level becomes smaller than in the case of mesa isolation, and the subsequent resist coating patterning becomes easy.

Subsequently, a silicon oxide film or a silicon nitride film, which becomes a protective coat (not shown), is deposited to a thickness of 200 nm. Next, a resist 110 is left by resist patterning in a stepped portion ST of each device where the transmission line CP extends. Subsequently, heat treatment for reflow is performed at a temperature at which the resist 110 is softened to form the resist 110 shown in FIG. 2D. This resist 110 is to prevent disconnection of a transmission line 113 to be produced next in the stepped portion ST.

Next, a protecting film (not shown) is removed by etching from the anode-ohmic electrode 107 and the cathode-ohmic electrode 108 of the Gunn diode GD, from on the ohmic electrode 109 of the Schottky diode SD and from a Schottky electrode forming region 111 on the active layer 103.

Next, a contact hole is formed, and a conductive film 112 constructed of Ti (100 nm) and Au (100 nm) is deposited on the entire surface by the vapor deposition method or the like.

This conductive film 112 plays not only a role of a power feed for plate-forming the Au film 113 that constitutes the transmission line CP but also a role of the Schottky electrode of the Schottky diode SD.

Although both the Schottky electrode and the power feed metal are concurrently formed with the conductive film 112 in this embodiment, it is also acceptable to form the Schottky electrode after forming the ohmic electrode 109 of the Schottky diode SD. Also, a high melting point metal of W (tungsten) or Mo (molybdenum), a high melting point nitride, a high melting point silicide, Al (aluminum) or the like can be used as a Schottky electrode material. It is preferable to select a material that can form a stable Schottky barrier.

Next, a resist of 15 μm in thickness is applied to perform patterning of the region where the transmission line 113 is formed, and thereafter, Au is plated to a thickness of 9 μm.

Subsequently, the above resist is removed, and the unnecessary conductive film 112 is removed by etching. The resist 110 that has been subjected to reflow is also removed, and thereby the transmission line CP is completed as shown in FIG. 1.

The thus-fabricated Schottky diode SD has a small capacitance per unit area and is able to be easily produced since the active layer of the Gunn diode is thick and has a low density, and this allows a varactor of a large capacitance variance to be easily obtained.

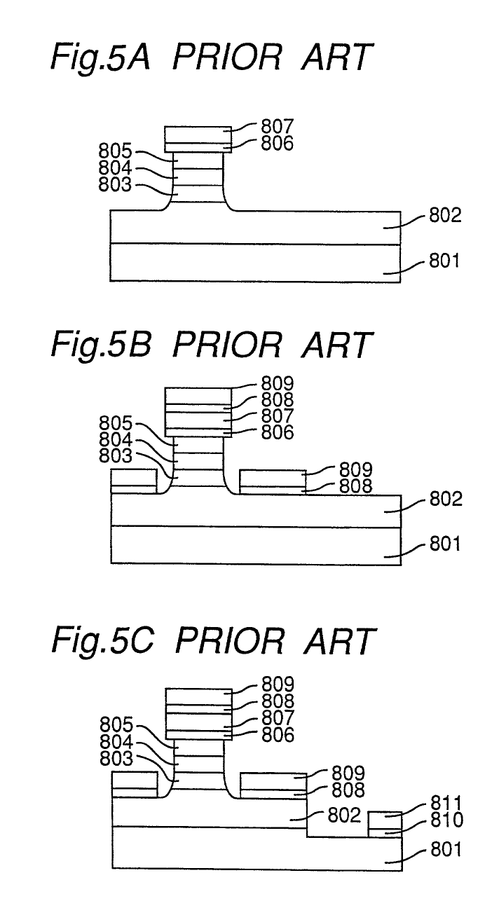

With this regard, both of the IMPATT diode of FIG. 5 and the Gunn diode of the present embodiment has such a structure as to oscillate in the milliwave band. However, the active layer of the IMPATT diode has a smaller thickness than that of the Gunn diode and requires a p-type n-type layer. This fact means that it is difficult to obtain a varactor diode of a small capacitance per unit area when the diode is fabricated by forming a Schottky electrode on the n-GaAs layer 803 of the IMPATT diode shown in FIG. 5. Specifically, the capacitance per unit area is large as exemplified by 1.5×10⁻⁷ (F/cm²) in FIG. 5 and 5×10⁻⁸ (F/cm²) in the present embodiment. This fact means that reduction of the device area is required in order to obtain a varactor of a small capacitance. However, fabrication of the varactor becomes difficult. Moreover, since the n-GaAs layer 803 has a small film thickness of 0.25 μm, the withstand voltage is low and the depletion layer less expands. Consequently, the capacitance variance is also reduced.

Although the transmission line CP is formed in a coplanar line in this embodiment, it may be formed in a microstrip line. Moreover, although the transmission line CP is formed with Au plating, Cu plating may be used so as to reduce fabrication cost.

The coplanar line is adopted for the transmission line in this embodiment. Particularly, when an NRD (non-radiative dielectric) guide is adopted in the milliwave band, a low-loss transmission line can be provided in comparison with the coplanar line and the microstrip line, and therefore this allows the prevention of performance degradation.

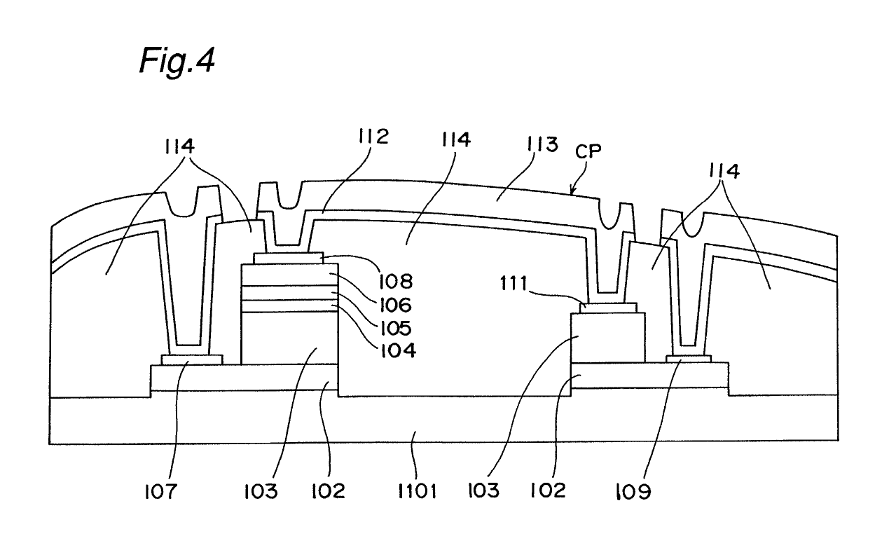

Moreover, in the fabricating process of this first embodiment, the resist 110 is formed at the stepped portion ST of each device and subjected to reflow so that the transmission line CP is not disconnected. However, instead of the reflow of the resist 110, it is acceptable to apply and form a flattening film 114 of polyimide, benzocyclobutene, spin-on-glass or the like as shown in FIG. 4.

In the above case, after formation of a contact hole mask, the flattening film 114 is processed by dry etching so as to form a contact hole on the electrodes 107, 108, 111 and 109. Subsequently, a transmission line CP constructed of the conductive film 112 and the Au film 113 is formed from the electrodes 107, 108, 111 and 109 onto the flattening film 114. In this case, since the contact hole mask is formed on the flattening film 114, photolithography of 1 μm or less can be easily achieved, which allows a minute contact hole to be formed. Therefore, the devices can be reduced in size for a fine structure.

Although a heterostructure of AlGaAs is employed as a cathode structure in the first embodiment, InGaP may be also used. This InGaP can be more easily subjected to selective etching in comparison with AlGaAs. Moreover, etching can be performed at a high selection ratio when a hydrochloric acid based etchant is used for this selective etching.

Although the GaAs/AlGaAs based semiconductor is employed in the aforementioned embodiment, other semiconductors that generate a negative resistance may be employed. For example, when an InP/InGaAs based semiconductor is employed instead of the GaAs/AlGaAs based semiconductor, characteristics such as efficiency at high frequencies of the Gunn diode are improved in comparison with the GaAs/AlGaAs system.

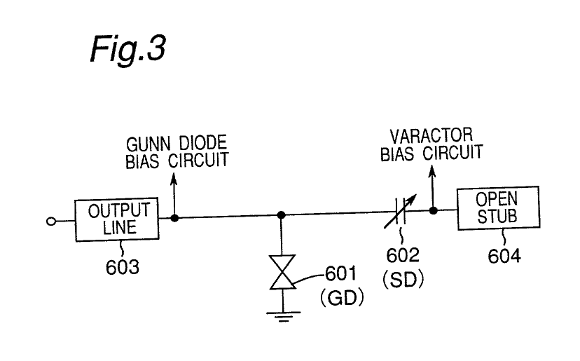

Next, a milliwave band oscillator that serves as a voltage-controlled oscillator according to a second embodiment of this invention will be described with reference to FIG. 3. According to the second embodiment, such a Gunn diode GD and a Schottky diode SD as described in the first embodiment are provided on a same substrate.

In this second embodiment, the Gunn diode GD formed in the region A of FIG. 1 is employed as an oscillation element 601, and the Schottky diode SD formed in the region B of FIG. 1 is employed as a varactor diode to provide a variable capacitor 602. The transmission line CP formed in the region C of FIG. 1 is employed as an output line 603 that has an impedance Zₒ of 50 Ω. Then, the variable capacitor 602 and a λ/4 wavelength open stub 604 are connected together to constitute a resonator.

In the milliwave band (30 to 90 GHz), if the Gunn diode GD and the Schottky diode SD are formed of different wafers and mounted to constitute a VCO (voltage-controlled oscillator), the line loss and the mounting loss such as wirebond loss are increased, as a consequence of which the Q-value is reduced to lead to performance degradation such as phase noise degradation.

According to the oscillator of this second embodiment, therefore, the Gunn diode GD that serves as the oscillation element and the Schottky diode SD are formed on the same substrate so as to reduce distance between transmission lines, and thereby the line loss reduction and the miniaturization are achieved.

In this case, capacitance of the varactor diode constructed of the Schottky diode SD is also changed by a device area of the Schottky diode SD. For example, the capacitance is about 50 (fF) under no bias application since the device area is 100 μm² when the active layer 103 of the first embodiment is employed in this embodiment. The capacitance is reduced when the depletion layer is expanded by biasing the Schottky diode SD. On the other hand, the capacitance is increased in proportion to the device area. Therefore, the variable capacitance range of the variable capacitor 602 constructed of the Schottky diode SD can flexibly be changed.

Furthermore, the capacitance of the variable capacitor 602 can also be adjusted by changing a density of the active layer 103. For example, when the density of the active layer 103 is increasingly inclined from a cathode interface toward an anode interface, the Schottky diode of a large capacitance variance can be obtained without impairing the characteristics of the Gunn diode. In this case, adjustment should be achieved within a range where the characteristics of the Gunn diode GD are not degraded. In addition, the active layer of the diode having a negative resistance is about 2000 nm in thickness in the milliwave band. The film thickness of the active layer is larger than thickness e.g. 500 nm of the collector layer of a bipolar transistor adapted for high frequency. Therefore, the expansion of the depletion layer is large. With this arrangement, the variable capacitance can be enlarged when the Schottky diode is employed as a varactor diode.

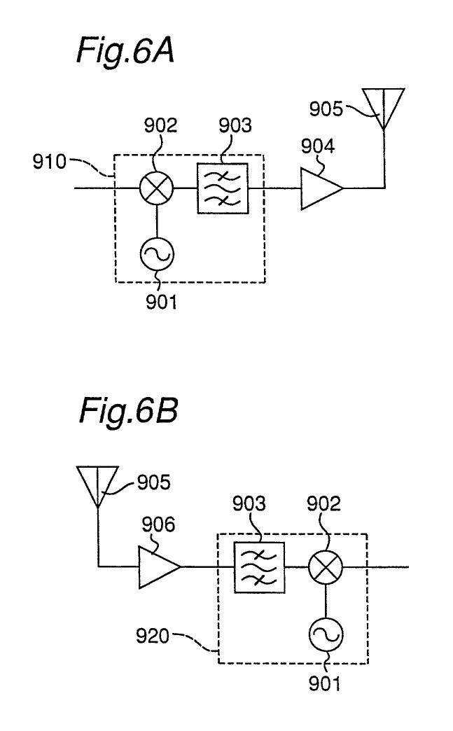

Next, a third embodiment of this invention will be described with reference to FIG. 6. FIG. 6A shows the construction of a millimeter wave transmitter provided with an oscillation circuit 910, while FIG. 6B shows the construction of a millimeter wave receiver provided with an oscillation circuit 920.

In the millimeter wave transmitter (and the millimeter wave receiver), a mixer 902 is connected to an oscillator 901 constructed of the voltage-controlled oscillator of the second embodiment. A filter 903 is connected to this mixer 902, and a power amplifier 904 (a low noise amplifier 906) is connected between an antenna 905 and a filter 903.

This mixer 902 is constructed of the Schottky diode SD formed in the region B of FIG. 1 of the first embodiment. The filter 903 is constructed of the transmission line CP formed in the region C of FIG. 1 of the first embodiment.

In this case, the high frequency characteristic is improved when thickness of the active layer 103 is reduced by control of etching in forming the Schottky diode SD, and thus the performance of the mixer 902 is also improved.

It is required to separately mount a transistor as the power amplifier 904 of the transmitter shown in FIG. 6A and the low noise amplifier 906 of the receiver shown in FIG. 6B. However, if a local signal from the oscillator 901 is sufficiently large, the power amplifier 904 and the low noise amplifier 906 are not necessary. This means that the transmitter and the receiver of the milliwave band can be made monolithic.

In the milliwave band, there occurs a problem that the mixer 902 cannot be operated with a large signal when the line loss is large between the oscillator 901 and the mixer 902. Therefore, it is very effective in loss reduction to reduce the line dimension by fabricating the Gunn diode GD that serves as the oscillation element and the Schottky diode SD that constitutes the mixer 902 on the same substrate.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

What is claimed is:

1. A semiconductor device comprising:
a negative resistance diode provided with an anode-ohmic electrode and a cathode-ohmic electrode having a negative resistance diode characteristic and an epitaxial structure; and
a Schottky diode provided with an active layer having a negative resistance diode characteristic and an epitaxial structure, a Schottky electrode formed on the active layer, and an ohmic electrode formed on an ohmic electrode forming high-density layer,
wherein the negative resistance diode and the Schottky diode are integratedly formed on a same substrate.

2. A semiconductor device as claimed in claim 1, wherein
the negative resistance diode and the Schottky diode are connected by a transmission line to be integratedly formed on the same substrate.

3. A semiconductor device as claimed in claim 1, wherein
the negative resistance diode is a Gunn diode.

4. A method for fabricating the semiconductor device claimed in claim 1 or 2, comprising the steps of:
exposing the active layer by removing by etching an anode-ohmic electrode forming high-density layer or a cathode-ohmic electrode forming high-density layer having the negative resistance diode characteristic and the epitaxial structure; and
forming the Schottky electrode on the active layer.

5. A method for fabricating a semiconductor device, the semiconductor device having:
a negative resistance diode having an epitaxial structure with a negative resistance diode characteristic, an anode-ohmic electrode and a cathode-ohmic electrode, the epitaxial structure having a heterostructure; and
a Schottky diode provided with an active layer having with a negative resistance diode characteristic and an epitaxial structure, a Schottky electrode formed on the active layer, and an ohmic electrode formed on an ohmic electrode forming high-density layer, wherein
the negative resistance diode and the Schottky diode are integratedly formed on a same substrate, the method comprising the steps of:
exposing a wide-band gap layer by removing by etching a cathode-ohmic electrode forming high-density layer;
exposing the active layer by removing by etching the wide-band gap layer; and
forming the Schottky electrode on the active layer.

6. A semiconductor device fabricating method as claimed in claim 5, wherein
the negative resistance diode is a Gunn diode.

7. An oscillator having a semiconductor device, comprising:
a negative resistance diode provided with an anode-ohmic electrode and a cathode-ohmic electrode having a negative resistance diode characteristic and an epitaxial structure;
a Schottky diode provided with an active layer having a negative resistance diode characteristic and an epitaxial structure, a Schottky electrode formed on the active layer, and an ohmic electrode formed on an ohmic electrode forming high-density layer; and
a transmission line connecting the negative resistance diode and the Schottky diode,
wherein the negative resistance diode, the Schottky diode and the transmission line are integratedly formed on a same substrate, and
wherein the negative resistance diode is served as an oscillation element, the Schottky diode is provided for a varactor diode, and the transmission line is provided for an output line and a stub.

8. An oscillator as claimed in claim 7, wherein
the negative resistance diode is a Gunn diode.
